(19) United States
(12) Patent Application Publication
(10) Pub. No.: US 2015/0041790 A1
(43) Pub. Date: Feb. 12, 2015

(54) Organic Light Emitting Display Device and Electronic Device Having the Same

(71) Applicant: Samsung Display Co., Ltd., Yongin-City (KR)

(72) Inventors: Kyoung-Soo Lee, Suwon-si (KR); Jong-Soo Kim, Hwaseong-si (KR); Tae-Jin Kim, Bucheon-si (KR)

(21) Appl. No.: 14/449,053

(22) Filed: Jul. 31, 2014

(30) Foreign Application Priority Data
Aug. 6, 2013 (KR) 10-2013-0092866

(51) Int. Cl. H01L 27/32

(52) U.S. Cl. CPC H01L 27/322; H01L 27/3244; H01L 27/3211
USPC 257/40

(57) ABSTRACT

An organic light emitting display device configured to employ a time division control technique by which one frame is divided into a first field and a second field, and the first field and the second field are sequentially driven includes a display unit. The display unit includes first emission control-lines and second emission control-lines alternately arranged along a first direction, wherein the first emission control-lines and the second emission control-lines extend along a second direction perpendicular to the first direction, and first pixel groups and second pixel groups, wherein the first pixel groups alternate with the second pixel groups along the second direction between the first emission control-lines and the second emission control-lines, wherein each of the first pixel groups is coupled to an adjacent one of the first emission control-lines, and each of the second pixel groups is coupled to an adjacent one of the second emission control-lines.

### CROSS-REFERENCE TO RELATED APPLICATION

This application claims priority to and the benefit of Korean Patent Applications No. 10-2013-0092866, filed on Aug. 6, 2013 in the Korean Intellectual Property Office (KIPO), the content of which is incorporated herein in its entirety by reference.

### BACKGROUND

1. Field

Example embodiments relate generally to a flat panel display device.

2. Description of the Related Art

Flat panel display (FPD) devices are widely used as the display device of electronic devices because FPD devices are relatively lightweight and thin compared to cathode-ray tube (CRT) display devices. Examples of FPD devices are liquid crystal display (LCD) devices and organic light emitting display (OLED) devices. Compared to liquid crystal display devices, OLED devices have many characteristics such as a relatively higher luminance and a relatively wider viewing angle. In addition, OLED devices can be made thinner because OLED devices do not require a backlight. In OLED devices, electrons and holes are injected into an organic thin layer through a cathode and an anode, and then recombined in the organic thin layer to generate excitons, thereby a light of a certain wavelength can be emitted.

OLED devices that employ a time division control technique may divide one frame into a plurality of sub-frames, and may control the sub-frames according to a desired grayscale. The sub-frames may correspond to bits of driving data, and may have different brightness ratios. In OLED devices that include red color pixels (i.e., pixels that emit a red color light), green color pixels (i.e., pixels that emit a green color light), and blue color pixels (i.e., pixels that emit a blue color light), the time division control method may be divided into a horizontal time division control (H-TDC) method that alternately drives adjacent pixels in a horizontal direction, and a vertical time division control (V-TDC) method that alternately drives adjacent pixels in a vertical direction. However, a color defect in a certain pattern and a flicker defect may occur in OLED devices that employ the time division control technique.

### SUMMARY

Example embodiments include an organic light emitting display device that employs a time division control technique configured to display a relatively stable-quality image in all patterns.

Example embodiments include an electronic device having an organic light emitting display device.

According to some embodiments, an organic light emitting display device is configured to employ a time division control technique by which one frame is divided into a first field and a second field, and the first field and the second field are sequentially driven. The organic light emitting display device includes: a display unit comprising: first emission control-lines and second emission control-lines alternately arranged along a first direction, wherein the first emission control-lines and the second emission control-lines extend along a second direction perpendicular to the first direction, and first pixel groups and second pixel groups, wherein the first pixel groups alternate with the second pixel groups along the second direction between the first emission control-lines and the second emission control-lines, wherein each of the first pixel groups is coupled to an adjacent one of the first emission control-lines, and each of the second pixel groups is coupled to an adjacent one of the second emission control-lines; a data driver configured to provide data signals to the display unit through a plurality of data-lines; an emission driver configured to provide first emission signals to the display unit through the first emission control-lines in the first field, and to provide second emission signals to the display unit through the second emission control-lines in the second field; a scan driver configured to sequentially provide scan signals to the display unit through a plurality of scan-lines; and a power unit configured to provide a power voltage to the display unit through a plurality of power-lines.

The first direction may be parallel to a short side of the display unit, and the second direction may be parallel to a long side of the display unit.

The first pixel groups may be configured to concurrently emit light in response to the first emission signals that are applied to the first emission control-lines in the first field; and the second pixel groups may be configured to concurrently emit light in response to the second emission signals that are applied to the second emission control-lines in the second field.

Each of the first pixel groups may include a red color pixel configured to emit a red color light, a green color pixel configured to emit a green color light, and a blue color pixel configured to emit a blue color light.

Each of the first pixel groups may include: a first organic light emitting diode configured to generate the red color light; a second organic light emitting diode configured to generate the green color light; a third organic light emitting diode configured to generate the blue color light; a common pixel circuit configured to generate a driving current that is applied to the first through third organic light emitting diodes; a first emission transistor configured to control an operation of the first organic light emitting diode by receiving the first emission signal through the first emission control-lines, the first emission transistor being coupled to the common pixel circuit; a second emission transistor configured to control an operation of the second organic light emitting diode by receiving the first emission signal through the first emission control-lines, the second emission transistor being coupled to the common pixel circuit; and a third emission transistor configured to control an operation of the third organic light emitting diode by receiving the first emission signal through the first emission control-lines, the third emission transistor being coupled to the common pixel circuit.

The common pixel circuit may be coupled to a data line of the data-lines and a scan line of the scan-lines, and the common pixel circuit may be configured to generate the driving current that is applied to the first through third organic light emitting diodes in response to a data signal of the data signals that is provided from the data driver and a scan signal of the scan signals that is provided from the scan driver.

Each of the first pixel groups may include: a first organic light emitting diode; a second organic light emitting diode; a third organic light emitting diode; a red color filter, a green color filter, and a blue color filter on the first organic light emitting diode, the second organic light emitting diode, and the third organic light emitting diode, respectively; a common pixel circuit configured to generate a driving current that is applied to the first through third organic light emitting diodes; a first emission transistor configured to control an operation of the first organic light emitting diode by receiving the first emission signal through the first emission control-lines, the first emission transistor being coupled to the common pixel circuit; a second emission transistor configured to control an operation of the second organic light emitting diode by receiving the first emission signal through the first emission control-lines, the second emission transistor being coupled to the common pixel circuit; and a third emission transistor configured to control an operation of the third organic light emitting diode by receiving the first emission signal through the first emission control-lines, the third emission transistor being coupled to the common pixel circuit.

The common pixel circuit may be coupled to a data line of the data-lines and a scan line of the scan-lines, and the common pixel circuit may be configured to generate the driving current that is applied to the first through third organic light emitting diodes in response to a data signal of the data signals that is provided from the data driver and a scan signal of the scan signals that is provided from the scan driver.

Each of the second pixel groups may include a red color pixel that emits a red color light, a green color pixel that emits a green color light, and a blue color pixel that emits a blue color light.

Each of the second pixel groups may include: a first organic light emitting diode configured to generate the red color light; a second organic light emitting diode configured to generate the green color light; a third organic light emitting diode configured to generate the blue color light; a common pixel circuit configured to generate a driving current that is applied to the first through third organic light emitting diodes; a first emission transistor configured to control an operation of the first organic light emitting diode by receiving the second emission signal through the second emission control-lines, the first emission transistor being coupled to the common pixel circuit; a second emission transistor configured to control an operation of the second organic light emitting diode by receiving the second emission signal through the second emission control-lines, the second emission transistor being coupled to the common pixel circuit; and a third emission transistor configured to control an operation of the third organic light emitting diode by receiving the second emission signal through the second emission control-lines, the third emission transistor being coupled to the common pixel circuit.

The common pixel circuit may be coupled to a data line of the data-lines and a scan line of the scan-lines, and the common pixel circuit may be configured to generate the driving current that is applied to the first through third organic light emitting diodes in response to a data signal of the data signals that is provided from the data driver and a scan signal of the scan signals that is provided from the scan driver.

Each of the second pixel groups may include: a first organic light emitting diode; a second organic light emitting diode; a third organic light emitting diode; a red color filter, a green color filter, and a blue color filter on the first organic fight emitting diode, the second organic light emitting diode, and the third organic light emitting diode, respectively; a common pixel circuit configured to generate a driving current that is applied to the first through third organic light emitting diodes; a first emission transistor configured to control an operation of the first organic light emitting diode by receiving the second emission signal through the second emission control-lines, the first emission transistor being coupled to the common pixel circuit; a second emission transistor configured to control an operation of the second organic light emitting diode by receiving the second emission signal through the second emission control-lines, the second emission transistor being coupled to the common pixel circuit; and a third emission transistor configured to control an operation of the third organic light emitting diode by receiving the second emission signal through the second emission control-lines, the third emission transistor being coupled to the common pixel circuit.

The common pixel circuit may be coupled to a data line of the data-lines and a scan line of the scan-lines, and the common pixel circuit may generate the driving current that is applied to the first through third organic light emitting diodes in response to a data signal of the data signals that is provided from the data driver and a scan signal of the scan signals that is provided from the scan driver.

According to some embodiments, an electronic device includes: a central processing unit, at least one function block, and an organic light emitting display device, wherein the organic light emitting display device is configured to employ a time division control technique by which one frame is divided into a first field and a second field, and the first field and the second field are sequentially driven, wherein the organic light emitting display device comprises: a display unit comprising first emission control-lines and second emission control-lines alternately arranged along a first direction, the first emission control-lines and the second emission control-lines extend along a second direction that is perpendicular to the first direction, and first pixel groups and second pixel groups, wherein the first pixel groups alternate with the second pixel groups along the second direction between the first emission control-lines and the second emission control-lines, wherein each of the first pixel groups is coupled to an adjacent one of the first emission control-lines, and each of the second pixel groups is coupled to adjacent one of the second emission control-lines; a data driver configured to provide a data signal to the display unit through a plurality of data-lines; an emission driver configured to provide first emission signals to the display unit through the first emission control-lines in the first field, and to provide second emission signals to the display unit through the second emission control-lines in the second field; a scan driver configured to sequentially provide scan signals to the display unit through a plurality of scan-lines; and a power unit configured to provide a power voltage to the display unit through a plurality of power-lines.

The first direction may be parallel to a short side of the display unit, and the second direction may be parallel to a long side of the display unit.

The first pixel groups may be configured to concurrently emit light in response to the first emission signals that are applied to the first emission control-lines in the first field; and the second pixel groups may be configured to concurrently emit light in response to the second emission signals that are applied to the second emission control-lines in the second field.

Each of the first pixel groups may include a red color pixel configured to emit a red color light, a green color pixel configured to emit a green color light, and a blue color pixel configured to emit a blue color light.

Each of the first pixel groups may include: a first organic light emitting diode configured to generate the red color light; a second organic light emitting diode configured to generate the green color light; a third organic light emitting diode configured to generate the blue color light; a common pixel circuit configured to generate a driving current that is applied to the first through third organic light emitting diodes; a first emission transistor configured to control an operation of the first organic light emitting diode by receiving the first emission signal through the first emission control-lines, the first emission transistor being coupled to the common pixel circuit; a second emission transistor configured to control an operation of the second organic light emitting diode by receiving the first emission signal through the first emission control-lines, the second emission transistor being coupled to the common pixel circuit; and a third emission transistor configured to control an operation of the third organic light emitting diode by receiving the first emission signal through the first emission control-lines, the third emission transistor being coupled to the common pixel circuit.

Each of the first pixel groups may include: a first organic light emitting diode; a second organic light emitting diode; a third organic light emitting diode; a red color filter, a green color filter, and a blue color filter on the first organic light emitting diode, the second organic light emitting diode, and the third organic light emitting diode, respectively; a common pixel circuit configured to generate a driving current that is applied to the first through third organic light emitting diodes; a first emission transistor configured to control an operation of the first organic light emitting diode by receiving the first emission signal through the first emission control-lines, the first emission transistor being coupled to the common pixel circuit; a second emission transistor configured to control an operation of the second organic light emitting diode by receiving the first emission signal through the first emission control-lines, the second emission transistor being coupled to the common pixel circuit; and a third emission transistor configured to control an operation of the third organic light emitting diode by receiving the first emission signal through the first emission control-lines, the third emission transistor being coupled to the common pixel circuit.

Each of the second pixel groups may include a red color pixel configured to emit a red color light, a green color pixel configured to emit a green color light, and a blue color pixel configured to emit a blue color light.

Each of the second pixel groups may include: a first organic light emitting diode configured to generate the red color light; a second organic light emitting diode configured to generate the green color light; a third organic light emitting diode configured to generate the blue color light; a common pixel circuit configured to generate a driving current that is applied to the first through third organic light emitting diodes; a first emission transistor configured to control an operation of the first organic light emitting diode by receiving the second emission signal through the second emission control-lines, the first emission transistor being coupled to the common pixel circuit; a second emission transistor configured to control an operation of the second organic light emitting diode by receiving the second emission signal through the second emission control-lines, the second emission transistor being coupled to the common pixel circuit; and a third emission transistor configured to control an operation of the third organic light emitting diode by receiving the second emission signal through the second emission control-lines, the third emission transistor being coupled to the common pixel circuit.

Each of the second pixel groups may include: a first organic light emitting diode; a second organic light emitting diode; a third organic light emitting diode; a red color filter, a green color filter, and a blue color filter on the first organic light emitting diode, the second organic light emitting diode, and the third organic light emitting diode, respectively; a common pixel circuit configured to generate a driving current that is applied to the first through third organic light emitting diodes; a first emission transistor configured to control an operation of the first organic light emitting diode by receiving the second emission signal through the second emission control-lines, the first emission transistor being coupled to the common pixel circuit; a second emission transistor configured to control an operation of the second organic light emitting diode by receiving the second emission signal through the second emission control-lines, the second emission transistor being coupled to the common pixel circuit; and a third emission transistor configured to control an operation of the third organic light emitting diode by receiving the second emission signal through the second emission control-lines, the third emission transistor being coupled to the common pixel circuit.

Therefore, an organic light emitting display device and an electronic device having the organic light emitting display device according to example embodiments may display a relatively stable-quality image in all patterns by dividing one frame into two fields, by driving pixel groups in zigzag shape, where each of the pixel groups includes one red color pixel, one green color pixel, and one blue color pixel.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating an organic light emitting display device according to example embodiments.

FIG. 2 is a diagram illustrating a display unit of an organic light emitting display device of FIG. 1.

FIG. 3 is a circuit diagram illustrating a plurality of pixel groups of a display unit of FIG. 2.

FIG. 4A is a cross-sectional diagram illustrating an example in which pixel groups of FIG. 3 are manufactured in a non-color filter configuration.

FIG. 4B is a cross-sectional diagram illustrating another example in which pixel groups of FIG. 3 are manufactured in a color filter configuration.

FIG. 5A is a circuit diagram illustrating an example of a common pixel circuit of pixel groups of FIG. 3.

FIG. 5B is a circuit diagram illustrating another example of a common pixel circuit of pixel groups of FIG. 3.

FIG. 6 is a flow chart illustrating a method of driving an organic light emitting display device according to example embodiments.

FIG. 7 is a diagram illustrating one frame of an organic light emitting display device that is applied to a method of FIG. 6.

FIGS. 8A through 8C are diagrams illustrating an example in which an organic light emitting display device is driven by a method of FIG. 6.

FIG. 9 is a block diagram illustrating an electronic device according to example embodiments.

FIG. 10 is a diagram illustrating an example in which an electronic device of FIG. 9 is implemented as a smart-phone.

### DETAILED DESCRIPTION

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. When an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

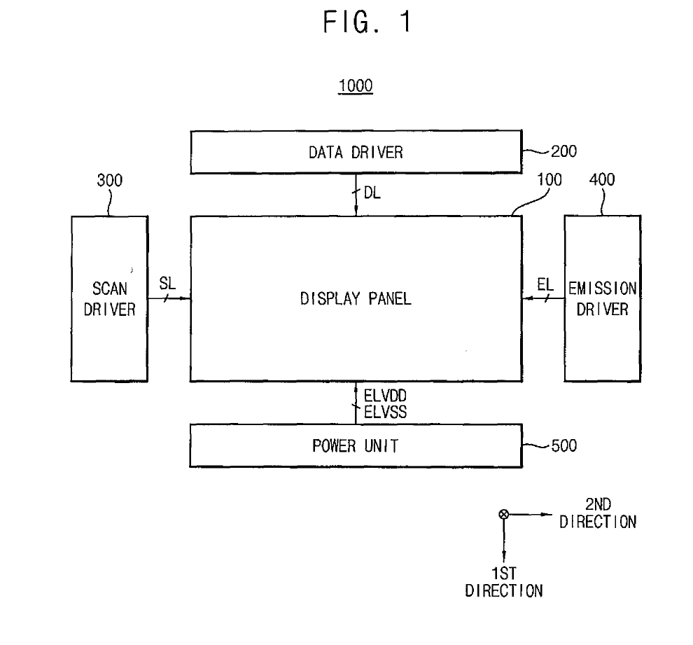

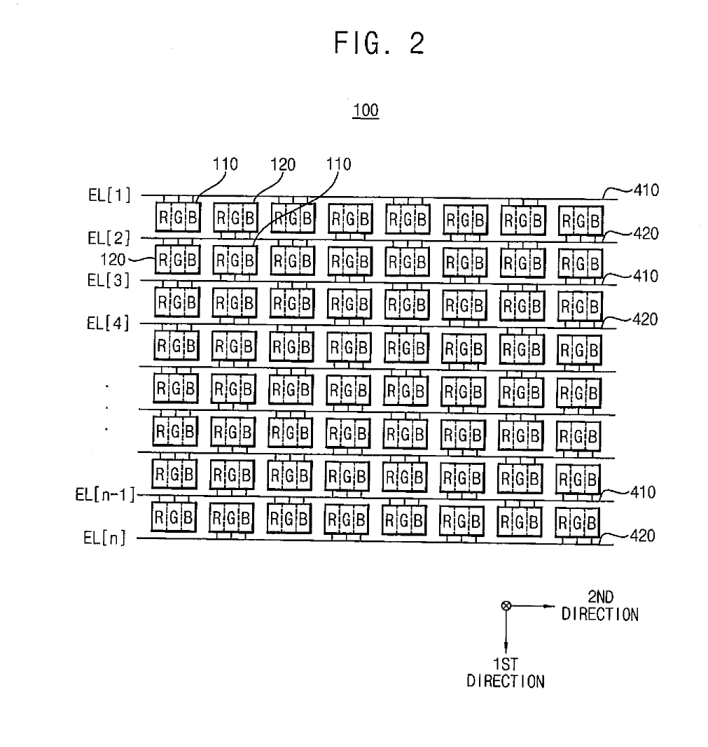

FIG. 1 is a block diagram illustrating an organic light emitting display device according to example embodiments. FIG. 2 is a diagram illustrating a display unit of an organic light emitting display device of FIG. 1.

Referring to FIG. 1 and FIG. 2, the organic light emitting display device 1000 may include a display unit or panel 100, a data driver 200, a scan driver 300, an emission driver 400, and a power unit 500.

The display unit 100 may display an image based on a data signal received from the data driver 200 through data-lines DL, a scan signal received from the scan driver 300 through scan-lines SL, an emission signal received from the emission driver 400 through emission control-lines EL, and power voltages ELVDD and ELVSS received from the power unit 500 through power-lines.

As illustrated in FIG. 2, the display unit 100 includes the emission control-lines EL[1] through EL[n], where n is an even number greater than or equal to 2, a plurality of first pixel groups 110, and a plurality of second pixel groups 120. The emission control-lines EL[1] through EL[n] are arranged in a first direction (e.g. a direction that is parallel to a short side of the display unit 100). Here, the emission control-lines EL[1] through EL[n] extend in a second direction (e.g. a direction that is parallel to a long side of the display unit 100).

The first pixel groups 110 and the second pixel groups 120 are adjacently arranged in an alternating order between the emission control-lines EL[1] through EL[n] in (e.g., along) the second direction (e.g. a direction that is parallel to a long side of the display unit 100).

The emission control-lines EL[1] through EL[n] may include a plurality of first emission control-lines 410 and a plurality of second emission control-lines 420. The first emission control-lines 410 may correspond to odd emission control-lines (i.e., EL[1], EL[3], EL[n−1]) among the emission control-lines EL[1] through EL[n], and the second emission control-lines 420 may correspond to even emission control-lines (i.e., EL[2], EL[4], EL[n]) among the emission control-lines ELM through EL[n]. In other words, the first emission control-lines 410 and the second emission control-lines 420 may be alternately arranged in an alternating order in (e.g., along) the first direction (e.g., a direction that is parallel to a short side of the display 100).

In the organic light emitting display device 1000 that employs a time division control technique by which one frame is divided into a first field and a second field, and the first field and the second field are sequentially driven, a first emission signal may be provided through the first emission control-lines 410 in the first field, and a second emission signal may be provided through the second emission control-lines 420 in the second field.

The first pixel groups 110 and the second pixel groups 120 may be adjacently arranged in an alternating order between the emission control-lines EL[1] through EL[n] in (e.g., along) the second direction. In detail, when one first pixel group 110 is positioned between the first emission control-lines 410 and the second emission control-lines 420 that are adjacently arranged in an alternating order in the first direction (e.g. a direction that is parallel to a short side of the display unit 100), the second pixel groups 120 may be arranged adjacently to the first pixel group 110 in the first direction (e.g. a direction that is parallel to a short side of the display unit 100) and also the second direction (e.g. a direction that is parallel to a long side of the display unit 100). Further, when one second pixel group 120 is positioned between the first emission control-lines 410 and the second emission control-lines 420 that are adjacently arranged in an alternating order in (e.g., along) the first direction (e.g. a direction that is parallel to a short side of the display unit 100), the first pixel groups 110 may be arranged adjacently to the second pixel group 120 in the first direction (e.g. a direction that is parallel to a short side of the display unit 100) and the second direction (e.g. a direction that is parallel to a long side of the display unit 100). In conclusion, the first pixel groups 110 and the second pixel groups 120 are alternately arranged in the first direction (e.g. a direction that is parallel to a short side of the display unit 100) and the second direction (e.g. a direction that is parallel to a long side of the display unit 100).

Each of the first pixel groups 110 includes a red color pixel that emits a red color light, a green color pixel that emits a green color light, and a blue color pixel that emits a blue color light. Here, the first pixel groups 110 concurrently (e.g., simultaneously) emit light in the first field, where the first pixel groups 110 are coupled to adjacent one of the first emission control-lines 410. Each of the second pixel groups 120 includes a red color pixel that emits a red color light, a green color pixel that emits a green color light, and a blue color pixel that emits a blue color light. Here, the second pixel groups 120 concurrently (e.g., simultaneously) emit light in the second field, where the second pixel groups 120 are coupled to adjacent one of the second emission control-lines 420.

As described above, the first pixel groups 110 and the second pixel groups 120 are alternately arranged in the first direction and the second direction. In addition, the first pixel groups 110 emit light in the first field, and the second pixel groups 120 emit light in the second field. Thus, the organic light emitting display device 1000 may emit light in a zigzag shape during respective fields of one frame (e.g., the first field and the second field).

As illustrated in FIG. 1, the data driver 200 may provide the data signals to the display unit 100 through the data-lines DL. The data signals control an operation of driving transistors, where the data signals are applied to common pixel circuits of the first pixel groups 110 and the second pixel groups 120 in the display unit 100. The data-lines DL extend in the first direction (e.g. a direction that is parallel to a short side of the display unit 100), and the data-lines DL are arranged in the second direction (e.g. a direction that is parallel to a long side of the display unit 100). According to a structure of the common pixel circuit of the first pixel groups 110 and the second pixel groups 120, the data signal may be provided to the red color pixel, the green color pixel, and the blue color pixel through different data-lines DL. Alternatively, the data signals may be provided to the red color pixel, the green color pixel, and the blue color pixel through the same data-line DL.

The scan driver 300 may provide the scan signals to the display unit 100 through the scan-lines SL. The scan signals control an operation of switching transistors, where the scan signals are applied to the common pixel circuit of the first pixel groups 110 and the second pixel groups 120 in the display unit 100. The scan-lines SL extend in the second direction (e.g. a direction that is parallel to a long side of the display unit 100), and the scan-lines SL are arranged in (e.g., along) the first direction (e.g. a direction that is parallel to a short side of the display unit 100). According to the structure of the common pixel circuit, the scan data may be provided to the first pixel groups 110 and the second pixel groups 120 through different scan-lines SL. Alternatively, the scan signals may be provided to the first pixel groups 110 and the second pixel groups 120 through the same scan-line SL.

The emission driver 400 may provide the first emission signals and the second emission signals to the display unit 100 through the emission control-lines EL. The first emission signals control light emission operations of organic light emitting diodes of the first pixel groups 110, where the first emission signals are applied to emission control transistors of the first pixel groups 110 in the display unit 100. The second emission signals control a light emission operation of organic light emitting diodes of the second pixel groups 120, where the second emission signals are applied to emission control transistors of the second pixel groups 120 in the display unit 100. The emission control-lines EL extend in the second direction (e.g. a direction that is parallel to a long side of the display unit 100), and the emission control-lines EL are arranged in the first direction (e.g. a direction that is parallel to a short side of the display unit 100). Here, odd emission control-lines among the emission control-lines may correspond to the first emission control-lines 410 and even emission control-lines among the emission control-lines may correspond to the second emission control-lines 420. The first emission signals may be provided through the first emission control-lines 410 in the first field, and the second emission signals may be provided through the second emission control-lines 420 in the second field.

The power unit 500 may provide a high power voltage ELVDD and a low power voltage ELVSS to the first and second pixel groups through the power-lines.

A timing controller (not illustrated in FIG. 1) may generate a plurality of control signals, and may control the data driver 200, the scan driver 300, the emission driver 400, and the power unit 500 by providing the control signals to the data driver 200, the scan driver 300, the emission driver 400, and the power unit 500.

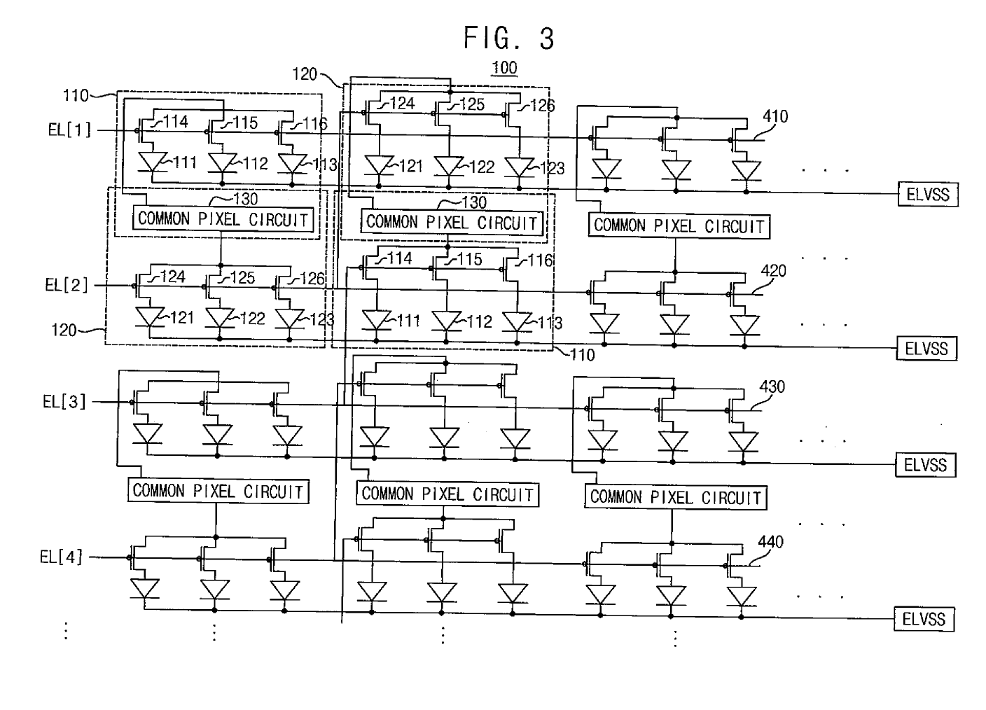

FIG. 3 is a circuit diagram illustrating a plurality of pixel groups of a display unit of FIG. 2.

Referring to FIG. 3, the first pixel groups 110 and the second pixel groups 120 which are adjacently arranged in the first direction (e.g., a direction that is parallel to a short side of the display unit 100) may share a driving current which is provided to organic light emitting diodes from the common pixel circuit 130.

In detail, each of the first pixel groups 110 include the red color pixel, the green color pixel, and the blue color pixel. Thus, each of the first pixel groups 110 include a first organic light emitting diode 111, a second organic light emitting diode 112, a third organic light emitting diode 113, the common pixel circuit 130, a first emission control transistor 114, a second emission control transistor 115, and a third emission control transistor 116.

The first organic light emitting diode 111 of the first pixel groups 110 may emit light when the first emission control transistor 114 is turned-on. In the first field, when the first emission signal is provided through the first emission control-lines 410, the first emission control transistor 114 of the first pixel groups 110 may be turned-on. Thus, the driving current generated by the common pixel circuit 130 may be applied to the first organic light emitting diode 111 of the first pixel groups 110. As a result, the red color pixel may emit a red color light. The second organic light emitting diode 112 of the first pixel groups 110 may emit light when the second emission control transistor 115 of the first pixel groups 110 is turned-on. In the first field, when the first emission signal is provided through the first emission control-lines 410, the second emission control transistor 115 of the first pixel groups 110 may be turned-on. Thus, the driving current generated by the common pixel circuit 130 may be applied to the second organic light emitting diode 112 of the first pixel groups 110. As a result, the green color pixel may emit a green color light. The third organic light emitting diode 113 of the first pixel groups 110 may emit light when the third emission control transistor 116 of the first pixel groups 110 is turned-on. In the first field, when the first emission signal is provided through the first emission control-lines 410, the third emission control transistor 116 of the first pixel groups 110 may be turned-on. Thus, the driving current generated by the common pixel circuit 130 may be applied to the third organic light emitting diode 113 of the first pixel groups 110. As a result, the blue color pixel may emit a blue color light.

The common pixel circuit 130 may generate the driving current which drives the first organic light emitting diode 111 of the first pixel groups 110, the second organic light emitting diode 112 of the first pixel groups 110, and the third organic light emitting diode 113 of the first pixel groups 110. The common pixel circuit 130 may receive the data signal, the scan signal, and the power signal, and may generate the driving current based on the data signal, the scan signal, and the power signal.

Each of the second pixel groups 120 includes a first organic light emitting diode 121, a second organic light emitting diode 122, a third organic light emitting diode 123, the common pixel circuit 130, a first emission control transistor 124, a second emission control transistor 125, and a third emission control transistor 126.

The first organic light emitting diode 121 of the second pixel groups 120 may emit light when the first emission control transistor 124 of the second pixel groups 120 is turned-on. In the second field, when the second emission signal is provided through the second emission control-lines 420, the first emission control transistor 124 of the second pixel groups 120 may be turned-on. Thus, the driving current generated by the common pixel circuit 130 may be applied to the first organic light emitting diode 121 of the second pixel groups 120. As a result, the red color pixel may emit a red color light. The second organic light emitting diode 122 of the second pixel groups 120 may emit light when the second emission control transistor 125 of the second pixel groups 120 is turned-on. In the second field, when the second emission signal is provided through the second emission control-lines 420, the second emission control transistor 125 of the second pixel groups 120 may be turned-on. Thus, the driving current generated by the common pixel circuit 130 may be applied to the second organic light emitting diode 122 of the second pixel groups 120. As a result, the green color pixel may emit a green color light. The third organic light emitting diode 123 of the second pixel groups 120 may emit light when the third emission control transistor 126 of the second pixel groups 120 is turned-on. In the second field, when the second emission signal is provided through the second emission control-lines 420, the third emission control transistor 126 of the second pixel groups 120 may be turned-on. Thus, the driving current generated by the common pixel circuit 130 may be applied to the third organic light emitting diode 124 of the second pixel groups 120. As a result, the blue color pixel may emit a blue color light.

The common pixel circuit 130 may generate the driving current which drives the first organic light emitting diode 121, the second organic light emitting diode 122 and the third organic light emitting diode 123 in the second pixel groups 120. The common pixel circuit 130 may receive the data signal, the scan signal and the power signal, and may generate the driving current based on the data signal, the scan signal, and the power signal.

In brief, the common pixel circuit 130 may be shared by the first pixel groups 110 and the second pixel groups 120 which are adjacently arranged in the first direction (e.g. the minor-axis direction of the display unit 100). That is, the driving current generated by the common pixel circuit 130 may be applied to the first pixel groups 110 in the first field. Thus, the first pixel group 110 may emit light. The driving current generated by the common pixel circuit 130 may be applied to the second pixel groups 120 in the second field. Thus, the second pixel group 120 may emit light.

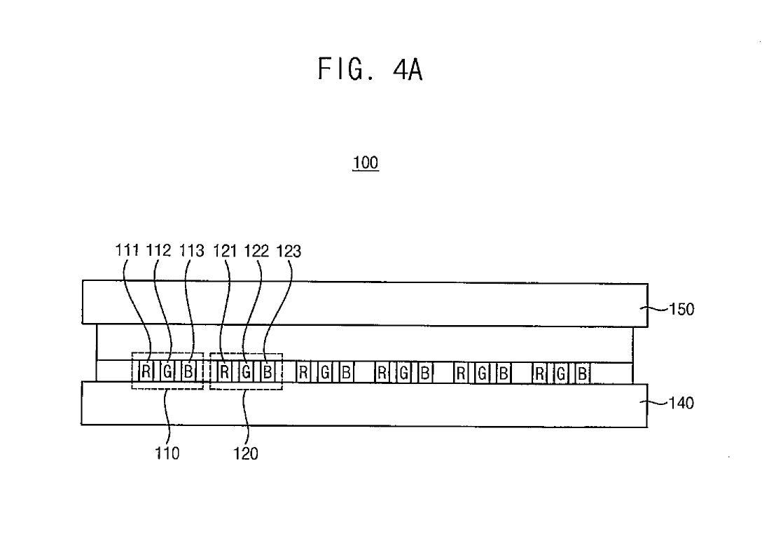

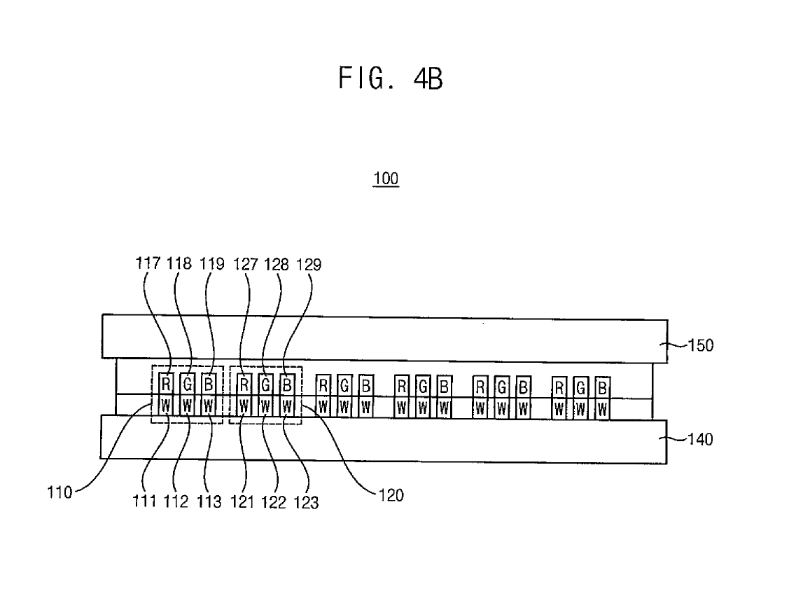

FIG. 4A is a cross-sectional diagram illustrating an example in which pixel groups of FIG. 3 are manufactured in a non-color filter configuration. FIG. 4B is a cross-sectional diagram illustrating another example in which pixel groups of FIG. 3 are manufactured in a color filter configuration.

Referring to FIG. 4A, a display unit 100 may include a first substrate 140, a second substrate 150, the first pixel groups 110, and the second pixel groups 120.

The first pixel groups 110 and the second pixel groups 120 may be formed on the first substrate 140.

Each of the first pixel groups 110 include the red color pixel, the green color pixel, and the blue color pixel. Here, the red color pixel includes the first organic light emitting diode 111, which emits red color light, the green color pixel includes the second organic light emitting diode 112, which emits green color light, and the blue color pixel includes the third organic light emitting diode 113, which emits blue color light. Each of the first organic light emitting diode 111, the second organic light emitting diode 112, and the third organic light emitting diode 113 may be formed on the first substrate 140 by sequentially stacking an anode electrode, a hole injection layer, an light emitting layer, an electron transport layer, and a cathode electrode. Here, a color of light emitted by the organic light emitting diode may be determined according to organic materials included in the light emitting layer.

The second pixel groups 120 may be adjacently arranged to the first pixel groups 110. Each of the second pixel group 120 also includes the red color pixel, the green color pixel and the blue color pixel. Here, the red color pixel includes the first organic light emitting diode 121, which emits red color light, the green color pixel includes the second organic light emitting diode 122, which emits green color light and the blue color pixel includes the third organic light emitting diode 123, which emits blue color light.

After forming an additionally layer (e.g., an encapsulation layer) on the first substrate 140, which has the first pixel groups 110 and the second pixel groups 120, the organic light emitting display device may be manufactured by positioning the second substrate opposite to the first substrate 140.

Referring to FIG. 4B, a display unit 100 includes a first substrate 140, a second substrate 150, a plurality of color filters, the first pixel group 110, and the second pixel group 120.

The first pixel groups 110 and the second pixel groups 120 include organic light emitting diodes, which emit white color light. Thus, the color filters (e.g., a red color filter 117, a green color filter 118, and a blue color filter 119) may be positioned on the organic light emitting diodes to emit red color light, green color light, and blue color light, respectively.

Each of the first pixel groups 110 includes the red color pixel, the green color pixel, and the blue color pixel. The red color pixel includes the first organic light emitting diode 111 which emits white color light on which the red color filter 117 is positioned, the green color pixel includes the second organic light emitting diode 112 which emits white color light on which the green color filter 118 is positioned, and the blue color pixel includes the third organic light emitting diode 113 which emits white color light on which the blue color filter 119 is positioned. The first organic light emitting diode 111, the second organic light emitting diode 112 and the third organic light emitting diode 113 may be formed on the first substrate 140 by sequentially stacking an anode electrode, a hole injection layer, an light emitting layer, an electron transport layer, and a cathode electrode. Here, the first organic light emitting diode 111, the second organic light emitting diode 112, and the third organic light emitting diode 113 may be manufactured by forming the organic light emitting layer with organic materials that result in white color light. The red color filter 117, the green color filter 118, and the blue color filter 119 are formed on the organic light emitting diodes 111, 112, and 113, respectively. Here, the red color filter 117, the green color filter 118, and the blue color filter 119 may be formed by any suitable color filter formation method.

The second pixel groups 120 may be adjacently arranged to the first pixel groups 110. Each of the second pixel groups 120 includes the red color pixel, the green color pixel, and the blue color pixel. The red color pixel includes the first organic light emitting diode 121, which emits white color light on which the red color filter 127 is positioned, the green color pixel includes the second organic light emitting diode 122 which emits white color light on which the green color filter 128 is positioned, and the blue color pixel includes the third organic light emitting diode 123 which emits white color light on which the blue color filter 129 is positioned.

After forming an additional layer (e.g., an encapsulation layer) on the first substrate 140 which has the first pixel groups 110 and the second pixel groups 120, the organic light emitting display device may be manufactured by positioning the second substrate opposite to the first substrate 140.

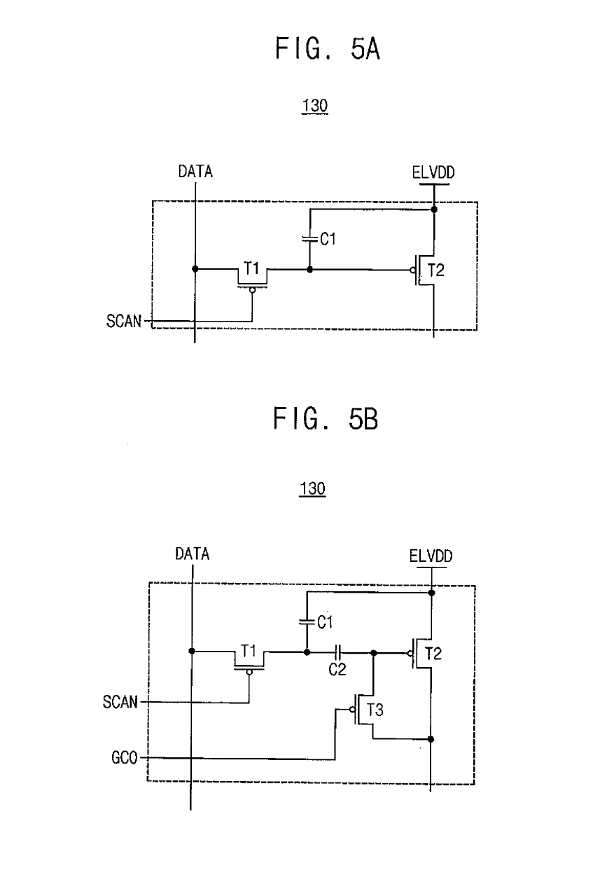

FIG. 5A is a circuit diagram illustrating an example of a common pixel circuit of pixel groups illustrated in FIG. 3. FIG. 5B is a circuit diagram illustrating another example of a common pixel circuit of pixel groups illustrated in FIG. 3.

Referring to FIG. 5A, the common pixel circuit 130 may have a basic structure of 2T-1C (i.e., two transistors and one capacitor) that generates the driving current of the organic light emitting diode. The common pixel circuit 130 may include a switching transistor T1, a storage capacitor C1, and a driving transistor T2.

A first terminal of the switching transistor T1 is coupled to the data-line. A second terminal of the switching transistor T1 is coupled to the storage capacitor C1. The gate electrode of the switching transistor T1 is coupled to the scan-line. A gate electrode of the switching transistor T1 receives the scan signal SCAN from the scan driver. When the scan signal is applied, the switching transistor T1 is turned-on. The switching transistor T1 receives the data signal DATA through a data-line which is coupled to the first terminal of the switching transistor T1. The switching transistor T1 transfers the data signal DATA to the storage capacitor C1.

The storage capacitor C1 stores the data signal DATA and controls an operation of the driving transistor T2.

A first terminal of the driving transistor T2 receives the power voltage signal ELVDD. The first terminal of the driving transistor T2 is coupled to the power-line. A second terminal of the driving transistor T2 is coupled to the first through third emission control transistors of the first pixel groups which are outside of the common pixel circuit 130. The second terminal of the driving transistor T2 is coupled to the first through third emission control transistors of the second pixel group, which are outside of the common pixel circuit 130. A gate electrode of the driving transistor T2 is coupled to the storage capacitor C1. The driving transistor T2 generates the driving current according to the data signal DATA, which is stored in the storage capacitor C1. The driving current may be applied to the organic light emitting diode according to an operation of the emission control transistor, which is coupled to the second terminal of the driving transistor T2.

Referring to FIG. 5B, the common pixel circuit 130 includes the switching transistor T1, the storage capacitor C1, the driving transistor T2, a compensation transistor T3, and a compensation capacitor C2.

A first terminal of the switching transistor T1 is coupled to the data-line. A second terminal of the switching transistor T1 is coupled to the storage capacitor C1. The gate electrode of the switching transistor T1 is coupled to the scan-line. A gate electrode of the switching transistor T1 receives the scan signal SCAN from the scan driver. When the scan signal is applied, the switching transistor T1 is turned-on. The switching transistor T1 receives the data signal DATA through a data-line, which is coupled to the first terminal of the switching transistor T1. The switching transistor T1 transfers the data signal DATA to the storage capacitor C1.

The storage capacitor C1 stores the data signal DATA and controls an operation of the driving transistor T2.

A first terminal of the driving transistor T2 receives the power voltage signal ELVDD. The first terminal of the driving transistor T2 is coupled to the power-line. A second terminal of the driving transistor T2 is coupled to the first through third emission control transistors of the first pixel groups which are outside of the common pixel circuit 130. The second terminal of the driving transistor T2 is coupled to the first through third emission control transistor of the second pixel groups which are outside of the common pixel circuit 130. A gate electrode of the driving transistor T2 is coupled to the storage capacitor C1. The driving transistor T2 generates the driving current according to the data signal DATA, which is stored in the storage capacitor C1. The driving current may be applied to the organic light emitting diode according to an operation of the emission control transistor which is coupled to the second terminal of the driving transistor T2.

A first terminal of the compensation transistor T3 is coupled to the compensation capacitor C2. A second terminal of the compensation transistor T3 is coupled to the second terminal of the driving transistor T2. A gate electrode of the compensation transistor T3 receives a compensation signal GCO. The compensation transistor T3 controls the driving current, which is applied to the first through third organic light emitting diodes of the first pixel groups and the second pixel groups.

The compensation capacitor C2 includes a first terminal, which is coupled to the storage capacitor C1 and the switching transistor T1, and a second terminal, which is coupled to the power-line.

Although a structure of the common pixel circuit 130 is illustrated in FIGS. 5A and 5B, the structure of the common pixel circuit 130 is not limited thereto.

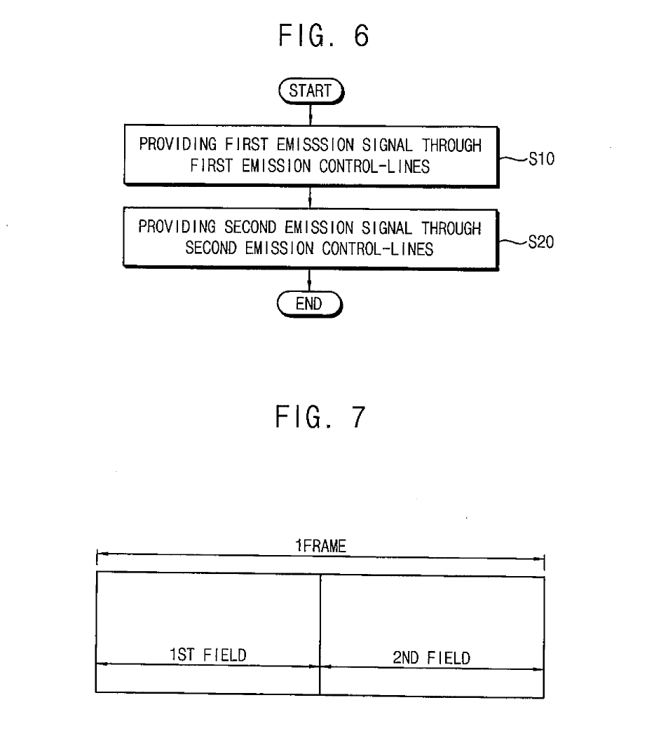

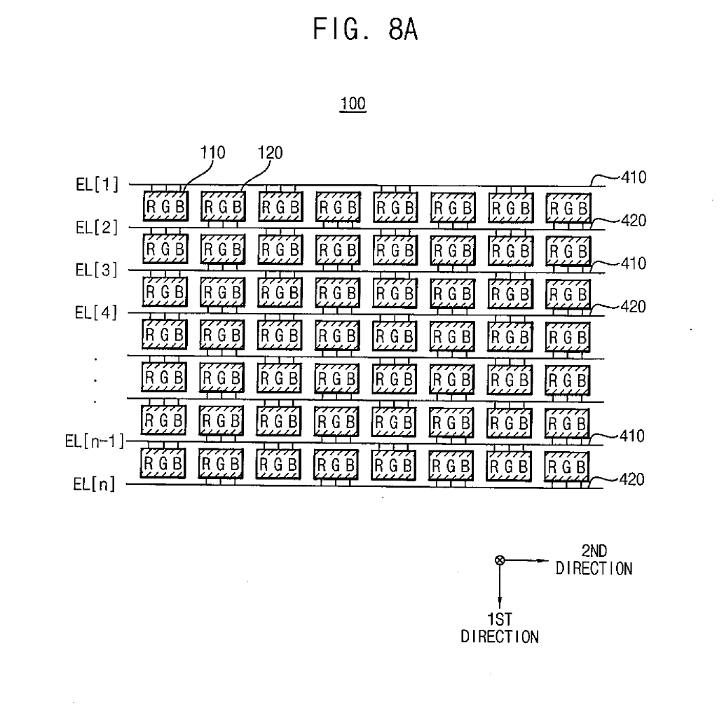

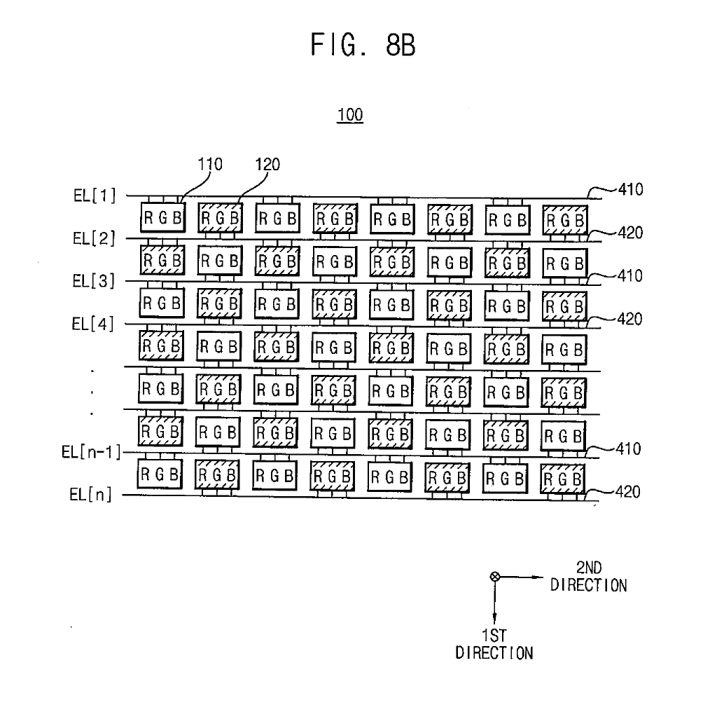

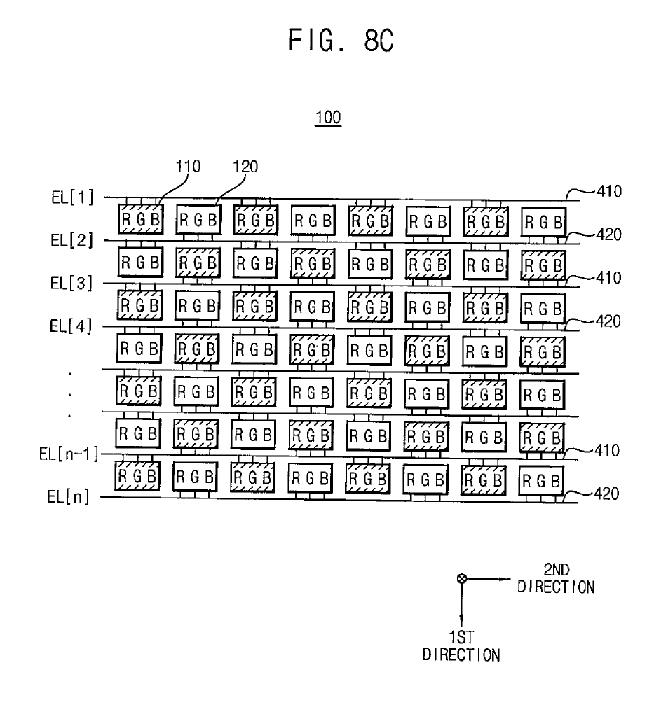

FIG. 6 is a flow chart illustrating a method of driving an organic light emitting display device according to example embodiments. FIG. 7 is a diagram illustrating one frame of an organic light emitting display device that is applied to a method of FIG. 6. FIGS. 8A through 8C are diagrams illustrating an example in which an organic light emitting display device is driven by a method of FIG. 6.

Referring to FIG. 6, the method of FIG. 6 may employ a time division control technique by which one frame is divided into a first field and a second field, and the first field and the second field are sequentially driven. Specifically, the method of FIG. 6 may provide a first emission signal through first emission control-lines in the first field (step S10), and may provide a second emission signal through second emission control-lines in the second field (step S20).

As described, the first pixel groups and the second pixel groups are alternately arranged in the first direction and the second direction. In addition, the first pixel groups emit light in the first field, and the second pixel groups emit light in the second field. Thus, the organic light emitting display device may emit light in a zigzag shape during respective fields of one frame (i.e., the first field and the second field), and the display unit 100 may be recognized that all pixels emit light in one frame.

Referring to FIG. 7, the organic light emitting display device which employs the time division control technique is driven by dividing one frame into the first field and the second field.

In a first field, a first emission signal is provided through first emission control-lines 410. Here, a red color pixel, a green color pixel, and a blue color pixel of first pixel groups 110, which are coupled to the first emission control-lines 410 emit light. The first pixel groups 110 emit light in a zigzag shape in the first field because second pixel groups 120 are adjacently arranged to the first pixel groups 110.

In a second field, a second emission signal is provided through second emission control-lines 420. Here, a red color pixel, a green color pixel and a blue color pixel of the second pixel groups 120, which are coupled to the second emission control-lines 420 emit light. The second pixel groups 120 emit light in the zigzag shape in the second field because the first pixel groups 110 are adjacently arranged to the second pixel group 120.

Referring to FIGS. 8A to 8C, in a display unit 100 of an organic light emitting display device, the first pixel groups 110 may emit light in the zigzag shape as illustrated in FIG. 8B in the first field because the first emission signal is provided from the emission driver through the first emission control-lines 410. The second pixel groups 120 may emit light in the zigzag shape as illustrated in FIG. 8C in the second field because the second emission signal is provided from the emission driver through the second emission control-lines 420. Although driving frequencies are different according to a kind of a display device, generally, a time for driving one frame is very short. Thus, the first pixel groups 110 and the second pixel groups 120 which emit light in the zigzag shape may be recognized that all pixels emit light in one frame as illustrated in FIG. 8A although the organic light emitting display device is driven by dividing one frame into the first field and the second field as illustrate in FIGS. 8B and 8C.

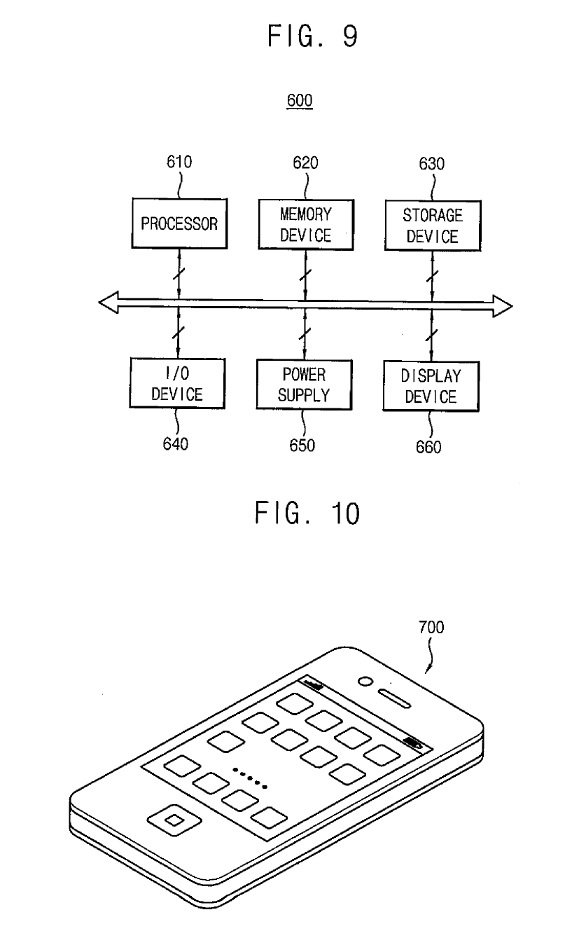

FIG. 9 is a block diagram illustrating an electronic device according to example embodiments. FIG. 10 is a diagram illustrating an example in which an electronic device of FIG. 9 is implemented as a smart-phone.

Referring to FIG. 9, the electronic device 600 may include a processor 610, a memory device 620, a storage device 630, an input/output (I/O) device 640, a power supply 650 and an organic light emitting display device 660. Here, the organic light emitting display device 660 may correspond to the organic light emitting display device 1000 of FIG. 1. In addition, the electronic device 600 may further include a plurality of ports for communicating a video card, a sound card, a memory card, a universal serial bus (USB) device, other electronic devices, etc. Although it is illustrated in FIG. 10 that the electronic device 600 is implemented as a smart-phone 700, a kind of the electronic device 600 is not limited thereto.

The processor 610 may perform various computing functions. The processor 610 may be a microprocessor, a central processing unit (CPU), etc. The processor 610 may be coupled to other components via an address bus, a control bus, a data bus, etc. Further, the processor 610 may be coupled to an extended bus such as peripheral component interconnect (PCI) bus. The memory device 620 may store data for operations of the electronic device 600. For example, the memory device 620 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, etc., and/or at least one volatile memory device such as a dynamic random access memory (DRAM) device, a static random access memory (SRAM) device, a mobile DRAM device, etc. The storage device 630 may be a solid state drive (SSD) device, a hard disk drive (HDD) device, a CD-ROM device, etc.

The I/O device 640 may be an input device such as a keyboard, a keypad, a touchpad, a touch-screen, a mouse, etc., and an output device such as a printer, a speaker, etc. In some example embodiments, the organic light emitting display device 660 may be included in the I/O device 640. The power supply 650 may provide a power for operations of the electronic device 600. The organic light emitting display device 660 may communicate with other components via the buses or other communication links.

As described above, the organic light emitting display device 660 may include a display unit, a data driver, a scan driver, an emission driver and a power unit, and may employ a time division control technique by which one frame is divided into a first field and a second field, and the first field and the second field are sequentially driven. Here, the organic light emitting display device 660 divides a plurality of pixels in the display unit into first pixel groups and second pixel groups, and alternately drives the first pixel groups and the second pixel groups in a zigzag shape in the first field and the second field. This method may improve a display defect in a certain pattern which occurs in the organic light emitting display device that employs a traditional time division control technique. Thus, the organic light emitting display device 660 which employs above method may display a relatively high-quality image.

The present inventive concept may be applied to an electronic device having an organic light emitting display device. For example, the present inventive concept may be applied to a computer monitor, a laptop, a digital camera, a cellular phone, a smart phone, a smart pad, a television, a personal digital assistant (PDA), a portable multimedia player (PMP), a MP3 player, a navigation system, a game console, a video phone, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and aspects of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims, and their equivalents.

What is claimed is:

1. An organic light emitting display device configured to employ a time division control technique by which one frame is divided into a first field and a second field, and the first field and the second field are sequentially driven, the organic light emitting display device comprising:
a display unit comprising:
first emission control-lines and second emission control-lines alternately arranged along a first direction, wherein the first emission control-lines and the second emission control-lines extend along a second direction perpendicular to the first direction, and
first pixel groups and second pixel groups, wherein the first pixel groups alternate with the second pixel groups along the second direction between the first emission control-lines and the second emission control-lines, wherein each of the first pixel groups is coupled to an adjacent one of the first emission control-lines, and each of the second pixel groups is coupled to an adjacent one of the second emission control-lines;
a data driver configured to provide data signals to the display unit through a plurality of data-lines;
an emission driver configured to provide first emission signals to the display unit through the first emission control-lines in the first field, and to provide second emission signals to the display unit through the second emission control-lines in the second field;
a scan driver configured to sequentially provide scan signals to the display unit through a plurality of scan-lines; and
a power unit configured to provide a power voltage to the display unit through a plurality of power-lines.

2. The organic light emitting display device of claim 1, wherein the first direction is parallel to a short side of the display unit, and the second direction is parallel to a long side of the display unit.

3. The organic light emitting display device of claim 1, wherein the first pixel groups are configured to concurrently emit light in response to the first emission signals that are applied to the first emission control-lines in the first field; and
wherein the second pixel groups are configured to concurrently emit light in response to the second emission signals that are applied to the second emission control-lines in the second field.

4. The organic light emitting display device of claim 3, wherein each of the first pixel groups comprises a red color pixel configured to emit a red color light, a green color pixel configured to emit a green color light, and a blue color pixel configured to emit a blue color light.

5. The organic light emitting display device of claim 4, wherein each of the first pixel groups comprises:
a first organic light emitting diode configured to generate the red color light;
a second organic light emitting diode configured to generate the green color light;
a third organic light emitting diode configured to generate the blue color light;
a common pixel circuit configured to generate a driving current that is applied to the first through third organic light emitting diodes;
a first emission transistor configured to control an operation of the first organic light emitting diode by receiving the first emission signal through the first emission control-lines, the first emission transistor being coupled to the common pixel circuit;
a second emission transistor configured to control an operation of the second organic light emitting diode by receiving the first emission signal through the first emission control-lines, the second emission transistor being coupled to the common pixel circuit; and
a third emission transistor configured to control an operation of the third organic light emitting diode by receiving the first emission signal through the first emission control-lines, the third emission transistor being coupled to the common pixel circuit.

6. The organic light emitting display device of claim 5, wherein the common pixel circuit is coupled to a data line of the data-lines and a scan line of the scan-lines, and wherein the common pixel circuit is configured to generate the driving current that is applied to the first through third organic light emitting diodes in response to a data signal of the data signals that is provided from the data driver and a scan signal of the scan signals that is provided from the scan driver.

7. The organic light emitting display device of claim 4, wherein each of the first pixel groups comprises:
a first organic light emitting diode;
a second organic light emitting diode;
a third organic light emitting diode;
a red color filter, a green color filter, and a blue color filter on the first organic light emitting diode, the second organic light emitting diode, and the third organic light emitting diode, respectively;
a common pixel circuit configured to generate a driving current that is applied to the first through third organic light emitting diodes;
a first emission transistor configured to control an operation of the first organic light emitting diode by receiving the first emission signal through the first emission control-lines, the first emission transistor being coupled to the common pixel circuit;
a second emission transistor configured to control an operation of the second organic light emitting diode by receiving the first emission signal through the first emission control-lines, the second emission transistor being coupled to the common pixel circuit; and
a third emission transistor configured to control an operation of the third organic light emitting diode by receiving the first emission signal through the first emission control-lines, the third emission transistor being coupled to the common pixel circuit.

8. The organic light emitting display device of claim 7, wherein the common pixel circuit is coupled to a data line of the data-lines and a scan line of the scan-lines, and the common pixel circuit is configured to generate the driving current that is applied to the first through third organic light emitting diodes in response to a data signal of the data signals that is provided from the data driver and a scan signal of the scan signals that is provided from the scan driver.

9. The organic light emitting display device of claim 3, wherein each of the second pixel groups comprises a red color pixel that emits a red color light, a green color pixel that emits a green color light, and a blue color pixel that emits a blue color light.

10. The organic light emitting display device of claim 9, wherein each of the second pixel groups comprises:
a first organic light emitting diode configured to generate the red color light;
a second organic light emitting diode configured to generate the green color light;
a third organic light emitting diode configured to generate the blue color light;
a common pixel circuit configured to generate a driving current that is applied to the first through third organic light emitting diodes;
a first emission transistor configured to control an operation of the first organic light emitting diode by receiving the second emission signal through the second emission control-lines, the first emission transistor being coupled to the common pixel circuit;
a second emission transistor configured to control an operation of the second organic light emitting diode by receiving the second emission signal through the second emission control-lines, the second emission transistor being coupled to the common pixel circuit; and
a third emission transistor configured to control an operation of the third organic light emitting diode by receiving the second emission signal through the second emission control-lines, the third emission transistor being coupled to the common pixel circuit.

11. The organic light emitting display device of claim 10, wherein the common pixel circuit is coupled to a data line of the data-lines and a scan line of the scan-lines, and the common pixel circuit is configured to generate the driving current that is applied to the first through third organic light emitting diodes in response to a data signal of the data signals that is provided from the data driver and a scan signal of the scan signals that is provided from the scan driver.

12. The organic light emitting display device of claim 9, wherein each of the second pixel groups comprises:
a first organic light emitting diode;
a second organic light emitting diode;
a third organic light emitting diode;
a red color filter, a green color filter, and a blue color filter on the first organic light emitting diode, the second organic light emitting diode, and the third organic light emitting diode, respectively;
a common pixel circuit configured to generate a driving current that is applied to the first through third organic light emitting diodes;
a first emission transistor configured to control an operation of the first organic light emitting diode by receiving the second emission signal through the second emission control-lines, the first emission transistor being coupled to the common pixel circuit;
a second emission transistor configured to control an operation of the second organic light emitting diode by receiving the second emission signal through the second emission control-lines, the second emission transistor being coupled to the common pixel circuit; and
a third emission transistor configured to control an operation of the third organic light emitting diode by receiving the second emission signal through the second emission control-lines, the third emission transistor being coupled to the common pixel circuit.

13. The organic light emitting display device of claim 12, wherein the common pixel circuit is coupled to a data line of the data-lines and a scan line of the scan-lines, and the common pixel circuit generates the driving current that is applied to the first through third organic light emitting diodes in response to a data signal of the data signals that is provided from the data driver and a scan signal of the scan signals that is provided from the scan driver.

14. An electronic device comprising:
a central processing unit, at least one function block, and an organic light emitting display device, wherein the organic light emitting display device is configured to employ a time division control technique by which one frame is divided into a first field and a second field, and the first field and the second field are sequentially driven,
wherein the organic light emitting display device comprises:
a display unit comprising
first emission control-lines and second emission control-lines alternately arranged along a first direction, the first emission control-lines and the second emission control-lines extend along a second direction that is perpendicular to the first direction, and
first pixel groups and second pixel groups, wherein the first pixel groups alternate with the second pixel groups along the second direction between the first emission control-lines and the second emission control-lines, wherein each of the first pixel groups is coupled to an adjacent one of the first emission control-lines, and each of the second pixel groups is coupled to adjacent one of the second emission control-lines;
a data driver configured to provide a data signal to the display unit through a plurality of data-lines;
an emission driver configured to provide first emission signals to the display unit through the first emission control-lines in the first field, and to provide second emission signals to the display unit through the second emission control-lines in the second field;
a scan driver configured to sequentially provide scan signals to the display unit through a plurality of scan-lines; and
a power unit configured to provide a power voltage to the display unit through a plurality of power-lines.

15. The electronic device of claim 14, wherein the first direction is parallel to a short side of the display unit, and the second direction is parallel to a long side of the display unit.

16. The electronic device of claim 15, wherein the first pixel groups are configured to concurrently emit light in response to the first emission signals that are applied to the first emission control-lines in the first field; and
wherein the second pixel groups are configured to concurrently emit light in response to the second emission signals that are applied to the second emission control-lines in the second field.

17. The electronic device of claim 16, wherein each of the first pixel groups comprises a red color pixel configured to emit a red color light, a green color pixel configured to emit a green color light, and a blue color pixel configured to emit a blue color light.

18. The electronic device of claim 17, wherein each of the first pixel groups comprises:
a first organic light emitting diode configured to generate the red color light;
a second organic light emitting diode configured to generate the green color light;
a third organic light emitting diode configured to generate the blue color light;
a common pixel circuit configured to generate a driving current that is applied to the first through third organic light emitting diodes;
a first emission transistor configured to control an operation of the first organic light emitting diode by receiving the first emission signal through the first emission control-lines, the first emission transistor being coupled to the common pixel circuit;
a second emission transistor configured to control an operation of the second organic light emitting diode by receiving the first emission signal through the first emission control-lines, the second emission transistor being coupled to the common pixel circuit; and
a third emission transistor configured to control an operation of the third organic light emitting diode by receiving the first emission signal through the first emission control-lines, the third emission transistor being coupled to the common pixel circuit.

19. The electronic device of claim 17, wherein each of the first pixel groups comprises:
a first organic light emitting diode;
a second organic light emitting diode;
a third organic light emitting diode;
a red color filter, a green color filter, and a blue color filter on the first organic light emitting diode, the second organic light emitting diode, and the third organic light emitting diode, respectively;
a common pixel circuit configured to generate a driving current that is applied to the first through third organic light emitting diodes;
a first emission transistor configured to control an operation of the first organic light emitting diode by receiving the first emission signal through the first emission control-lines, the first emission transistor being coupled to the common pixel circuit;
a second emission transistor configured to control an operation of the second organic light emitting diode by receiving the first emission signal through the first emission control-lines, the second emission transistor being coupled to the common pixel circuit; and
a third emission transistor configured to control an operation of the third organic light emitting diode by receiving the first emission signal through the first emission control-lines, the third emission transistor being coupled to the common pixel circuit.

20. The electronic device of claim 16, wherein each of the second pixel groups comprises a red color pixel configured to emit a red color light, a green color pixel configured to emit a green color light, and a blue color pixel configured to emit a blue color light.

21. The electronic device of claim 20, wherein each of the second pixel groups comprises:
a first organic light emitting diode configured to generate the red color light;
a second organic light emitting diode configured to generate the green color light;
a third organic light emitting diode configured to generate the blue color light;
a common pixel circuit configured to generate a driving current that is applied to the first through third organic light emitting diodes;
a first emission transistor configured to control an operation of the first organic light emitting diode by receiving the second emission signal through the second emission control-lines, the first emission transistor being coupled to the common pixel circuit;
a second emission transistor configured to control an operation of the second organic light emitting diode by receiving the second emission signal through the second emission control-lines, the second emission transistor being coupled to the common pixel circuit; and
a third emission transistor configured to control an operation of the third organic light emitting diode by receiving the second emission signal through the second emission control-lines, the third emission transistor being coupled to the common pixel circuit.

22. The electronic device of claim 20, wherein each of the second pixel groups comprises:
a first organic light emitting diode;
a second organic light emitting diode;
a third organic light emitting diode;
a red color filter, a green color filter, and a blue color filter on the first organic light emitting diode, the second organic light emitting diode, and the third organic light emitting diode, respectively;
a common pixel circuit configured to generate a driving current that is applied to the first through third organic light emitting diodes;
a first emission transistor configured to control an operation of the first organic light emitting diode by receiving the second emission signal through the second emission control-lines, the first emission transistor being coupled to the common pixel circuit;
a second emission transistor configured to control an operation of the second organic light emitting diode by receiving the second emission signal through the second emission control-lines, the second emission transistor being coupled to the common pixel circuit; and
a third emission transistor configured to control an operation of the third organic light emitting diode by receiving the second emission signal through the second emission control-lines, the third emission transistor being coupled to the common pixel circuit.
